(19) United States
(12) Patent Application Publication
(10) Pub. No.: US 2004/0040837 A1
(43) Pub. Date: Mar. 4, 2004

(54) Method of forming chalcogenide sputter target

(76) Inventors: Allen McTeer, Meridian, ID (US); Jiutao Li, Boise, ID (US); Terry L. Gilton, Boise, ID (US)

Correspondence Address: DICKSTEIN SHAPIRO MORIN & OSHINSKY LLP, 2101 L STREET NW, WASHINGTON, DC, 20037-1526, US

(21) Appl. No.: 10/230,281

(22) Filed: Aug. 29, 2002

(51) Int. Cl. C23C 14/32; C23C 14/00; B22F 1/02; B22F 1/00

(52) U.S. Cl. 204/192.26; 204/192.12; 419/48; 419/49; 419/30

(57) ABSTRACT

A method of fabricating a glass containing target for sputter deposition of a glass onto a substrate. The method includes synthesizing a glass from pure chemical element materials and then forming the synthesized glass into a powder, which is then used to form a glass containing target. In accordance with one aspect of the invention, the glass containing target may be used for sputter deposition of a thin coating of glass on a substrate. In exemplary embodiments, the glass is a chalcogenide glass target useful in fabricating memory devices.

### FIELD OF THE INVENTION

The invention relates to the field of memory devices formed using a chalcogenide glass, and in particular to, an improved method of fabricating a chalcogenide glass.

### BACKGROUND OF THE INVENTION

Noble metal doped chalcogenide glasses are presently of great interest for use in non-volatile memory devices, due to potential advantages in non-volatility, switching characteristics, memory speed, reliability, thermal characteristics, and durability, compared to other memory technologies. Research in this area is reported in the articles “High Speed Memory Behavior and Reliability of an Amorphous As₂S₃ Film doped with Ag” by Hirose et al., Phys. Stat. Sol. (1980), pgs. K187-K190; “Polarity-dependent memory switching and behavior of Ag dendrite in Ag-photodoped amorphous As₂S₃ films” by Hirose et al., Journal of applied Physics, Vol. 47, No. 6 (1976), pgs. 2767-2772; and “Dual Chemical Role of Ag as an Additive in Chalcogenide Glasses” by Mitkova et al., Physical Review Letters, Vol. 83, No. 19 (1999), pgs. 3848-3851, the disclosures of which are incorporated herein by reference.

Chalcogenide glass deposition is one of the most important aspects of fabricating a noble metal doped chalcogenide glass non-volatile memory device. For industrial applications, sputter deposition has many advantages compared to conventional evaporation deposition techniques. For example, sputter deposition provides better coating thickness and quality control. Furthermore, sputter deposition systems are more readily available for industrial applications.

Generally, sputter deposition, or sputtering, is performed by placing a substrate in a deposition chamber which is pressurized to a desired pressure. A particle stream of the coating material usually generated from a sputter target is then generated within the chamber and the coating or deposition occurs by condensation of the particles onto the substrate. In another sputtering technique, often referred to as ion beam bombardment sputtering, a high-energy source beam of ions is directed toward the sputter target. The force of the bombarding ions imparts sufficient energy to the atoms of the target to cause the energized atoms to leave the target and form a particle stream. The resulting deposition upon the substrate forms a thin coating.

Sputtering targets generally are made up of solid blocks of a selected chemical element or alloy. Some targets, for example, ceramic material targets, may be dry powders formed into a unitary porous structure, while other targets may be formed by mixing the material to be deposited into a binder-solvent slurry, casting the slurry into a mold, and applying heat to drive off the solvent. Such targets are prone to impurities (from the binder), frequent cracking from thermally-induced stresses, blistering (from embedded gasses), and difficulty in repairing targets damaged during the sputtering operation.

Chalcogenide glasses have many different composition or compound structures based on elements from group VI (S, Se, Te) combined with elements from group IV (Si, Ge) and group V (P, As, Sb, Bi). One method for preparing a chalcogenide glass coating sputter target is by grinding certain amounts of the desired elements, for example, germanium and selenium into powder and applying high pressure to form a press powder GeSe target.

The amount of germanium and selenium required are determined by the atomic percentages of germanium and selenium in the stoichiometric GeₓSe₁₀₀₋ₓ coating. For better electrical switching performance, selenium-rich (Se-rich) glass coatings are preferred. Selenium-rich glasses which incorporate a metal material are superionic conductors whereby the conductivity increases with metal content until a point of saturation. Selenium-rich glasses are generally those which have a selenium concentration higher than about 55 atomic percent.

Unfortunately, selenium-rich targets can be very difficult to produce, because of the low melting point of selenium (218° C.). It is even more difficult to produce targets having a selenium concentration higher than 70 atomic percent. Due to low sputter yield of glass containing targets, high sputtering power density is required in order to obtain acceptable wafer process throughput. High sputtering power corresponds with higher processing temperatures. Accordingly, the low selenium melting point frequently causes the sputter target to melt during high power or high thermal processing. Therefore, selenium-rich targets, particularly those having an atomic percent higher than 60% are difficult to use for sputter deposition.

It would be desirable to have an improved method of fabricating a glass containing sputter target and a glass coating. It would also be desirable to have a method of fabricating a glass containing sputter target and coating employing a low melting point chemical element.

### BRIEF SUMMARY OF THE INVENTION

An exemplary embodiment of the present invention includes a method of fabricating a chalcogenide glass containing sputter target for sputter deposition of a chalcogenide glass coating onto a substrate. The invention is particularly useful for depositing thin coatings formed from a chemical element having a low melting point component. The invention is also particularly useful for depositing a thin chalcogenide glass coating on a substrate during non-volatile memory element fabrication. The method includes synthesizing a glass from pure elemental materials and then grinding the glass into a powder and pressing the powder into a glass containing target. In accordance with one aspect of the invention, the glass containing target may be used for sputter deposition of a thin coating of glass on a substrate.

These and other features and advantages of the invention will be better understood from the following detailed description, which is provided in connection with the accompanying drawings.

### BRIEF DESCRIPTION OF THE DRAWINGS

FIG. 1 illustrates a process according to an exemplary embodiment of the present invention.

### DETAILED DESCRIPTION OF THE INVENTION

In the following detailed description, reference is made to various specific structural and process embodiments of the invention. These embodiments are described with sufficient detail to enable those skilled in the art to practice the invention. It is to be understood that other embodiments may be employed, and that various structural, logical and electrical changes may be made without departing from the spirit or scope of the invention.

The term “chalcogenide glass” is intended to include glasses that comprise at least one chemical element from group VIA of the periodic table. Group VIA elements, also referred to as chalcogens, include sulfur (S), selenium (Se), tellurium (Te), polonium (Po), and oxygen (O).

The present invention relates to a process for fabricating a glass containing target for sputter deposition of a glass coating onto a semiconductor substrate. In accordance with the invention, elements, for example, germanium and selenium, are used to synthesize a glass. The synthesized glass is then crushed or ground into a glass powder. The powder is then press molded into a glass containing target. The glass containing target may then be used in a sputter deposition process to deposit the glass coating on a substrate.

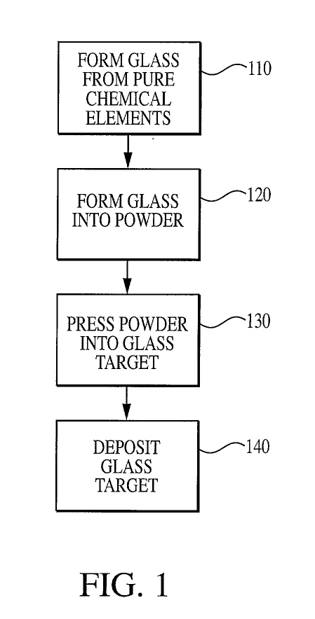

The invention will now be explained with reference to FIG. 1, which illustrates a process 100 according to an exemplary embodiment of the method of the invention.

Refer now to FIG. 1 at process segment 110 a bulk glass is formed from pure chemical elements. The bulk glass may be formed by any suitable technique. One preferred method includes starting from 99.999% pure chemical elements and reacting the chemical elements at high temperatures, preferably of about 1000° C. for at least about 24 hours in an evacuated (10⁻⁷ Torr) fused silica ampoule, followed by a cooling process, for example, rapid cool quenching process in order to obtain an amorphous state. Preferable pure chemical elements include chalcogenide glass combinations based on elements from group VI (sulfur (S), selenium (Se) and tellurium (Te)) combined with elements from group IV (silicon (Si) and germanium (Ge)) and group V (phosphorous (P), arsenic (As), antimony (Sb), and bismuth (Bi)). Although chalcogenide glass combinations are preferred, other chemical elements and glass combinations, which have a low melting point chemical element as a component, may be fabricated in accordance with the invention.

Next, at process segment 120, the bulk glass is ground into a powder. The bulk glass is preferably crushed and milled into a fine powder. The powder preferably will have a particle size of about 1 μm. Next at segment 130, the powder is then press molded into a glass containing target. The target maybe formed by any suitable means, including high pressure molding, press-molding under pressure at elevated temperatures, and hot pressing. By forming the glass and then forming the glass into a glass containing target, the thermal properties of the glass containing target will be determined by the properties of the glass as a whole instead of each individual pure chemical element of the glass.

In Differential Scanning Calorimeter (DSC) results of different chemical element sputter target materials indicate that the one chemical element melting dominates the thermal properties of a binary chemical element press powder target containing the chemical element. For example, the selenium melting point is the dominant thermal property of germanium-selenium press powder targets. As selenium has a melting point of about 218° C., which is lower than the glass transition temperature of, for example, Ge₄₀Se₆₀, the sputter target tends to melt during processing.

The thermal properties of a glass containing target, for example GeₓSe₁₀₀₋ₓ, are that of the glass as a whole structure and not that of the individual chemical elements. For example a Ge₄₀Se₆₀ glass containing target has a melting point of about 650° C., which is the same melting point as a Ge₄₀Se₆₀ glass. Accordingly, the melting point of the Ge₄₀Se₆₀ glass containing target is much higher than the melting point of a target containing elemental selenium (218° C.). Accordingly, targets formed from glass have a much better thermal durability than targets formed from elemental components of the glass. Glass containing targets also have much smoother and broader thermal transition ranges than chemical element formed targets.

In the next process segment 140 of FIG. 1, the glass containing target is deposited on a substrate preferably via sputter deposition. Any suitable deposition technique may be used. For example, pulse DC magnetron sputtering, RF (radio frequency) sputtering, or ion beam deposition (IBD) may be used. Suitable substrates include silicon wafers with thermal nitride or TEOS film. Suitable substrates also include silicon, silicon-on-insulator (SOI), silicon-on-sapphire (SOS), epitaxial layers of silicon supported by a base semiconductor foundation, and other semiconductor structures. Sputtering may also be done on other materials which are not semiconductors, such as plastic material.

The invention provides an improved process for fabricating glasses formed from low melting point chemical element. In particular the invention provides an improved process for fabricating selenium-rich glasses, i.e., glasses having a selenium concentration higher than about 55 atomic percent. Glasses fabricated in accordance with the invention have improved thermal properties, for example, improved thermal durability and higher melting points. As selenium-rich glasses, in particular, may be easily fabricated in accordance with the invention, memory devices incorporating glasses fabricated in accordance with the invention exhibit improved switching properties.

While an exemplary embodiment of the invention has been described and illustrated, many variations to the exemplary embodiment may be made without depositing from the spirit or scope of the invention. Accordingly, the invention is not limited by the foregoing description, but is only timely by the scope of the appended claims.

What is claimed as new and desired to be protected by Letters Patent of the United States is:

1. A method of making a target for deposition of a coating onto a substrate, comprising the steps of:
providing at least two pure chemical elements;
forming a glass from said pure chemical elements; and
forming a glass containing deposition target from said glass.

2. The method of claim 1 wherein one of said pure chemical elements is a chalcogen.

3. The method of claim 2 wherein at least one of said pure chemical elements comprises germanium.

4. The method of claim 2 wherein at least one of said pure chemical elements comprises selenium.

5. The method of claim 2 wherein one of said pure chemical elements comprises germanium and another of said pure chemical elements comprises selenium.

6. The method of claim 2 wherein said glass containing deposition target comprises a germanium-selenide compound.

7. The method of claim 6 wherein said germanium-selenide compound has a selenium concentration of higher than about 55 atomic percent.

8. The method of claim 7 wherein said germanium-selenide compound has a stoichiometry of about Ge₄₀Se₆₀.

9. The method of claim 1 wherein said glass containing deposition target has a melting point higher than a melting point of at least one of said pure chemical elements.

10. The method of claim 1 wherein said step of forming said glass comprises heating said pure chemical elements.

11. The method of claim 10 wherein said step of forming said glass comprises a cooling process.

12. The method of claim 1 wherein said step of forming said glass containing deposition target comprises changing said glass into a powder.

13. The method of claim 12 wherein said step of forming said glass containing deposition target comprises pressing said powder into a target.

14. The method of claim 1 further comprising depositing said glass containing deposition target onto a substrate.

15. The method of claim 14 wherein said depositing comprises a sputtering process.

16. The method of claim 15 wherein said sputtering process comprises a pulse DC magnetron sputtering process.

17. The method of claim 16 wherein said sputtering process comprises an RF sputtering process.

18. The method of claim 14 wherein said depositing comprises ion beam deposition.

19. The method of claim 13 wherein said pressing comprises applying heat.

20. A sputter target comprising the product made by claim 1.

21. A method of sputter depositing a coating on a substrate comprising:
providing at least two pure chemical element materials;
forming a glass from said pure chemical element materials;
forming a glass containing deposition target from said glass; and
sputter depositing said glass containing deposition target onto said substrate.

22. The method of claim 21 wherein at least one of said pure chemical element materials is a chalcogen element material.

23. The method of claim 22 wherein one of said pure chemical element materials comprises germanium.

24. The method of claim 22 wherein one of said pure chemical element materials comprises selenium.

25. The method of claim 22 wherein said pure chemical element materials comprise germanium and selenium.

26. The method of claim 22 wherein said glass containing deposition target comprises a germanium-selenide compound.

27. The method of claim 26 wherein said germanium-selenide compound has a selenium concentration of higher than about 55 atomic percent.

28. The method of claim 27 wherein said germanium-selenide compound has a stoichiometry of about Ge₄₀Se₆₀.

29. The method of claim 21 wherein said glass containing deposition target has a melting point higher than the melting point of at least one of said pure chemical element materials.

30. The method of claim 21 wherein said step of forming said glass comprises heating said pure chemical element materials.

31. The method of claim 30 wherein said step of forming said glass comprises a cooling process.

32. The method of claim 21 wherein said step of forming said glass containing deposition target comprises changing said glass into powder.

33. The method of claim 32 wherein said step of forming said glass containing deposition target comprises pressing said powder to form said glass containing deposition target.

34. The method of claim 21 further comprising depositing said glass containing deposition target onto a substrate.

35. The method of claim 34 wherein said depositing comprises a sputtering process.

36. The method of claim 35 wherein said sputtering process comprises a pulse DC magnetron sputtering process.

37. The method of claim 35 wherein said sputtering process comprises an RF sputtering process.

38. The method of claim 34 wherein said depositing comprises ion beam deposition.

39. The method of claim 33 wherein said pressing comprises applying heat.

40. A sputter target comprising the product made by claim 21.

41. A method of making a target for depositing of a coating onto a substrate comprising:
providing elemental germanium and elemental selenium;
forming a germanium-selenide glass having a formula represented as GeₓSe₁₀₀₋ₓ from said elemental germanium and said elemental selenium; and
forming a deposition target from said germanium-selenide glass.

42. The method of claim 41 wherein said germanium-selenide compound has a selenium concentration of higher than about 55 atomic percent.

43. The method of claim 41 wherein said germanium-selenide compound has a stoichiometry of about Ge₄₀Se₆₀.

44. The method of claim 41 wherein said germanium-selenide glass has a melting point higher than the melting point of said elemental selenium.

45. The method of claim 41 wherein said step of forming said germanium-selenide glass comprises heating said elemental germanium and said elemental selenium.

46. The method of claim 41 wherein said step of forming said germanium-selenide glass comprises reacting elemental germanium and elemental selenium.

47. The method of claim 46 wherein said step of forming said germanium-selenide glass comprises a cooling process.

48. The method of claim 41 wherein said step of forming said deposition target comprises changing said germanium-selenide glass into powder.

49. The method of claim 48 wherein said step of forming said deposition target comprises pressing said powder into said target.

50. The method of claim 41 further comprising depositing said deposition target onto a substrate.

51. The method of claim 50 wherein said depositing comprises a sputtering process.

52. The method of claim 51 wherein said sputtering process comprises a pulse DC magnetron sputtering process.

53. The method of claim 49 wherein said pressing comprises applying heat.

54. A target comprising the product made by claim 41.

55. The method of claim 51 wherein said sputtering process comprises an RF sputtering process.

56. The method of claim 51 wherein said sputtering process comprises an ion beam deposition process.

57. A sputter target comprising:
a glass powder compound pressed into a target, said compound comprising a plurality of fundamental materials formed into said glass.

58. A sputter target as in claim 57 wherein said plurality of fundamental materials comprises germanium and selenium.

59. A sputter target as in claim 57 wherein said glass powder compound has a stoichiometry of GeₓSe₁₀₀₋ₓ.
